(19) United States
(12) Patent Application Publication
(10) Pub. No.: US 2024/0090222 A1
(43) Pub. Date: Mar. 14, 2024

(54) SEMICONDUCTOR MEMORY DEVICE AND MANUFACTURING METHOD THEREFOR

(71) Applicant: Kioxia Corporation, Tokyo (JP)

(72) Inventors: Tatsufumi HAMADA, Nagoya Aichi (JP); Yosuke MITSUNO, Yokkaichi Mie (JP); Tomohiro KUKI, Yokkaichi Mie (JP); Yusuke MORIKAWA, Yokkaichi Mie (JP); Ryouji MASUDA, Yokkaichi Mie (JP); Hiroyasu SATO, Yokkaichi Mie (JP)

(21) Appl. No.: 18/460,303

(22) Filed: Sep. 1, 2023

(30) Foreign Application Priority Data
Sep. 8, 2022 (JP) 2022-143201

(51) Int. Cl. H10B 43/27

(52) U.S. Cl. CPC H10B 43/27

(57) ABSTRACT

A semiconductor memory device includes a stacked body in which a first insulating layer and a first conductive layer are alternately stacked in a first direction. A columnar body includes a first insulating portion extending in the first direction in the stacked body, a first semiconductor portion provided between the first insulating portion and the stacked body, and a third insulating portion provided between a second insulating portion provided between the first semiconductor portion and the stacked body, and the second insulating portion and the stacked body, and has a first end and a second end opposite to the first end. A second conductive layer is provided on the stacked body and is electrically connected to the first semiconductor portion at the first end of the columnar body. The first insulating portion blocks an inner side of the first semiconductor portion at the first end of the columnar body and has a space in the first semiconductor portion at a position closer to the second end than the first end.

### CROSS-REFERENCE TO RELATED APPLICATION(S)

This application is based upon and claims the benefit of priority from Japanese Patent Application No. 2022-143201, filed Sep. 8, 2022, the entire contents of which are incorporated herein by reference.

### FIELD

Embodiments described herein relate generally to a semiconductor memory device and a manufacturing method therefor.

### BACKGROUND

Some semiconductor memory devices, such as NAND flash memories, include 3-dimensional memory cell arrays in which memory cells are arrayed 3-dimensionally. When spaces such as voids or seams remain in memory holes of the memory cell arrays, metal materials of subsequently formed source layers introduce into the spaces of the memory holes, and thus characteristics of the memory cell arrays may deteriorate.

### DESCRIPTION OF THE DRAWINGS

FIG. 1 is a block diagram illustrating a semiconductor memory device and a memory controller;

FIG. 2 is a diagram illustrating an equivalent circuit of a part of a memory cell array;

FIG. 3 is a plan view illustrating a part of a semiconductor memory device according to a first embodiment;

FIG. 4 is a sectional view illustrating a part of the semiconductor memory device according to the first embodiment;

FIG. 5 is a sectional view illustrating a columnar body of the semiconductor memory device according to the first embodiment;

FIG. 6 is a sectional view illustrating a part of the semiconductor memory device according to the first embodiment;

FIG. 7 is a sectional view illustrating a configuration example of the columnar body;

FIG. 8 is a sectional view illustrating a configuration example of a columnar body according to a second embodiment;

FIG. 9 is a sectional view illustrating a configuration example of a columnar body according to a third embodiment;

FIG. 10 is a sectional view illustrating a configuration example of a columnar body according to a fourth embodiment;

FIG. 11 is a sectional view illustrating a configuration example of a columnar body according to a fifth embodiment;

FIG. 12 is a sectional view illustrating an example of a manufacturing method according to the fourth embodiment;

FIG. 13 is a sectional view illustrating the manufacturing method continued from FIG. 12;

FIG. 14 is a sectional view illustrating the manufacturing method continued from FIG. 13;

FIG. 15 is a sectional view illustrating the manufacturing method continued from FIG. 14;

FIG. 16 is a sectional view illustrating the manufacturing method continued from FIG. 15;

FIG. 17 is a sectional view illustrating the manufacturing method continued from FIG. 16;

FIG. 18 is a sectional view illustrating the manufacturing method continued from FIG. 17;

FIG. 19 is a sectional view illustrating the manufacturing method continued from FIG. 18;

FIG. 20 is a sectional view illustrating the manufacturing method continued from FIG. 19;

FIG. 21 is a sectional view illustrating the manufacturing method continued from FIG. 20;

FIG. 22 is a sectional view illustrating the manufacturing method continued from FIG. 21;

FIG. 23 is a sectional view illustrating the manufacturing method continued from FIG. 22;

FIG. 24 is a sectional view illustrating the manufacturing method continued from FIG. 23;

FIG. 25 is a sectional view illustrating the manufacturing method continued from FIG. 24;

FIG. 26 is a sectional view illustrating an example of a manufacturing method according to the fifth embodiment;

FIG. 27 is a sectional view illustrating an example of a manufacturing method according to the first embodiment;

FIG. 28 is a sectional view illustrating the manufacturing method continued from FIG. 27;

FIG. 29 is a sectional view illustrating the manufacturing method continued from FIG. 28;

FIG. 30 is a sectional view illustrating the manufacturing method continued from FIG. 29;

FIG. 31 is a sectional view illustrating an example of a manufacturing method according to the second embodiment; and

FIG. 32 is a sectional view illustrating the manufacturing method continued from FIG. 31.

### DETAILED DESCRIPTION

Embodiments provide a semiconductor memory device and a manufacturing method therefor capable of reducing deterioration in characteristics of a memory cell array.

In general, according to at least one embodiment, a semiconductor memory device includes a stacked body in which a first insulating layer and a first conductive layer are alternately stacked in a first direction. A columnar body includes a first insulating portion extending in the first direction in the stacked body, a first semiconductor portion provided between the first insulating portion and the stacked body, and a third insulating portion provided between a second insulating portion provided between the first semiconductor portion and the stacked body, and the second insulating portion and the stacked body, the columnar body having a first end and a second end opposite to the first end. A second conductive layer is provided on the stacked body and is electrically connected to the first semiconductor portion at the first end of the columnar body. The first insulating portion blocks an inner side of the first semiconductor portion at the first end of the columnar body and has a space in the first semiconductor portion at a position closer to the second end than the first end.

Hereinafter, embodiments of the present disclosure will be described with reference to the drawings. The present disclosure is not limited to the embodiments. In the following embodiments, the vertical direction of a semiconductor substrate may be different from the vertical direction according to the gravitational acceleration. The drawings are schematic and conceptual and ratios of portions and the like may not be the same as actual values. In the specification and the drawings, the same elements as the elements described in the above drawings are denoted by the same reference numerals and detailed description will be omitted appropriately.

### First Embodiment

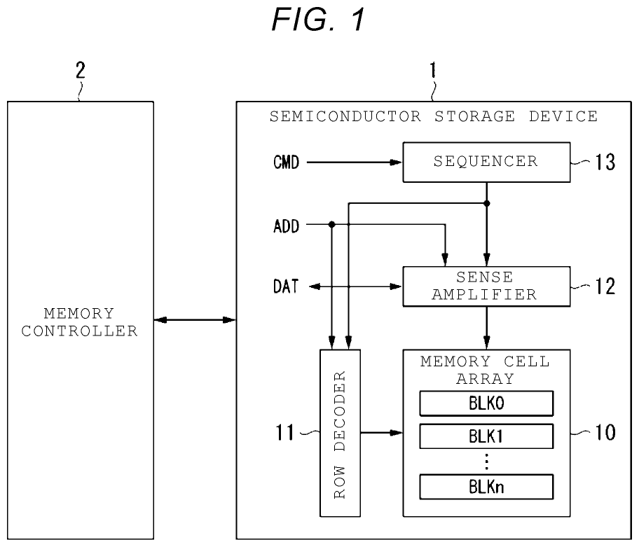

FIG. 1 is a block diagram illustrating a semiconductor memory device 1 and a memory controller 2. The semiconductor memory device 1 is a nonvolatile semiconductor memory device and is, for example, a NAND flash memory. The semiconductor memory device 1 includes, for example, a memory cell array 10, a row decoder 11, a sense amplifier 12, and a sequencer 13.

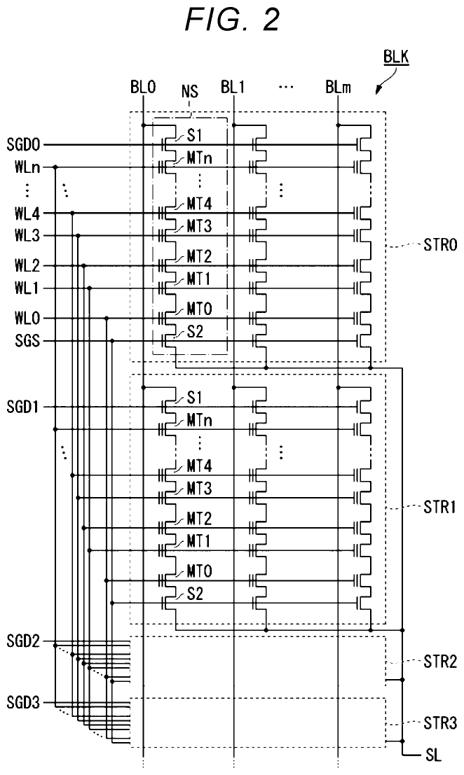

The memory cell array 10 includes a plurality of blocks BLK0 to BLKn (where n is an integer of 1 or more). Each block BLK is a set of nonvolatile memory cell transistors MT (see FIG. 2). In the memory cell array 10, a plurality of bit lines and a plurality of word lines are provided. Each memory cell transistor MT is connected to one bit line and one word line. A detailed configuration of the memory cell array 10 will be described below.

The row decoder 11 selects one block BLK based on address information ADD received from the external memory controller 2. The row decoder 11 controls a write operation and a read operation for data in and from the memory cell array 10 by applying a desired voltage to each of the plurality of word lines.

The sense amplifier 12 applies a desired voltage to each bit line in accordance with write data DAT received from the memory controller 2. The sense amplifier 12 determines data stored in the memory cell transistor MT based on a voltage of the bit line and transmits the determined read data DAT to the memory controller 2.

The sequencer 13 controls an operation of the entire semiconductor memory device 1 based on a command CMD received from the memory controller 2.

The above-described semiconductor memory device 1 and the memory controller 2 may configure one semiconductor device in such a combination. Examples of the semiconductor device include a memory card such as an SD (registered trademark) card or a solid-state drive (SSD).

Next, an electric configuration of the memory cell array 10 will be described.

FIG. 2 is a diagram illustrating an equivalent circuit of a part of the memory cell array 10. In FIG. 2, one extracted block BLK provided in the memory cell array 10 is illustrated. The block BLK includes a plurality (for example, four) strings STR0 to STR3.

The strings STR0 to STR3 are a set body of a plurality of NAND strings NS. One end of each NAND string NS is connected to any of the bit lines BL0 to BLm (where m is an integer of 1 or more). The other end of the NAND string NS is connected to a source line SL. Each NAND string NS includes a plurality of memory cell transistors MT0 to MTn (where n is an integer of 1 or more), a first select transistor S1, and a second select transistor S2.

The plurality of memory cell transistors MT0 to MTn are electrically connected to each other in series. The memory cell transistor MT includes a control gate and a memory film (for example, a charge storage film) and stores data in a nonvolatile manner. The memory cell transistor MT changes a state of the memory film in accordance with a voltage applied to the control gate (for example, stores charges in the charge storage film). The control gate of the memory cell transistor MT is connected to any corresponding word line of the word lines WL0 to WLn. The memory cell transistor MT is electrically connected to the row decoder 11 via the word line WL.

The first select transistor S1 in each NAND string NS is connected between the plurality of memory cell transistors MT0 to MTn and any of the bit lines BL0 to BLm. The drain of the first select transistor S1 is connected to any of the bit lines BL0 to BLm. The source of the first select transistor S1 is connected to the memory cell transistor MTn. The control gate of the first select transistor S1 in each NAND string NS is connected to any of select gate lines SGD0 to SGD3. The first select transistor S1 is electrically connected to the row decoder 11 via the select gate line SGD. The first select transistor S1 connects the NAND string NS and the bit line BL to each other when a predetermined voltage is applied to any of the select gate lines SGD0 to SGD3.

The second select transistor S2 in each NAND string NS is connected between the plurality of memory cell transistors MT0 to MTn and a source layer SL. The drain of the second select transistor S2 is connected to the memory cell transistor MT0. The source of the second select transistor S2 is connected to the source layer SL. The control gate of the second select transistor S2 is connected to the select gate line SGS. The second select transistor S2 is electrically connected to the row decoder 11 via the select gate line SGS. The second select transistor S2 connects the NAND string NS and the source layer SL to each other when a predetermined voltage is applied to the select gate line SGS.

The memory cell array 10 may have another circuit configuration other than the above-described configuration. For example, the number of strings STR provided in each block BLK and the numbers of the memory cell transistors MT and the select transistors STD and STS in each NAND string NS may be changed. The NAND string NS may include one or more dummy transistors.

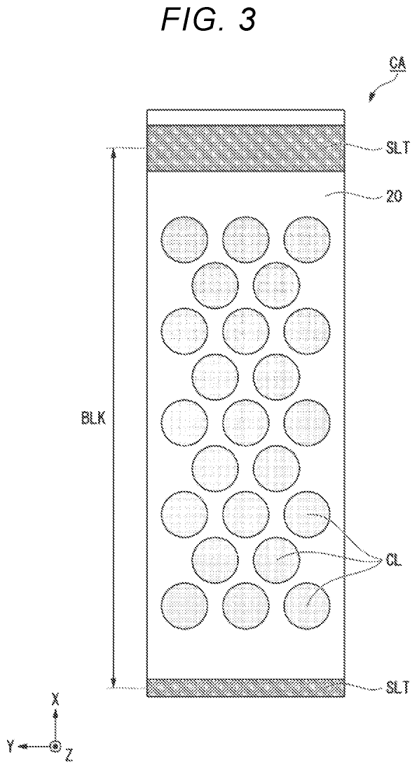

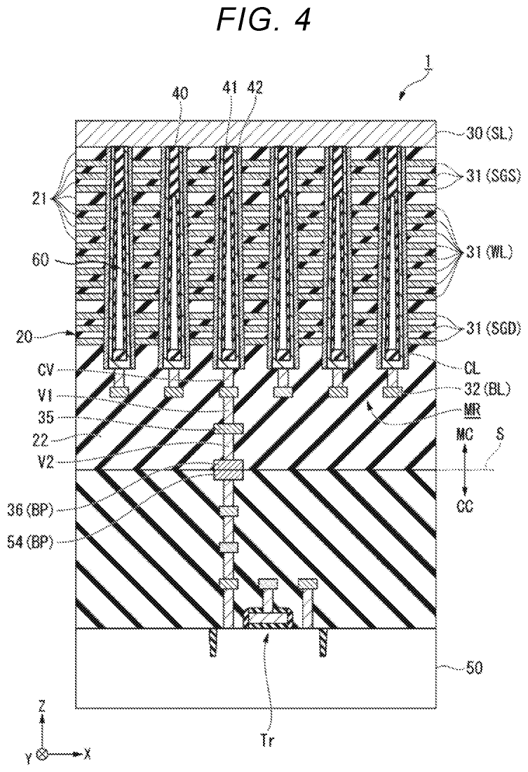

Next, an example of a structure of the semiconductor memory device 1 will be described. FIG. 3 is a plan view illustrating a part of the semiconductor memory device 1 according to the first embodiment. FIG. 4 is a sectional view illustrating a part of the semiconductor memory device 1 according to the first embodiment.

As illustrated in FIG. 4, the semiconductor memory device 1 is a 3-dimensional memory in which a memory chip MC and a circuit chip CC are bonded to each other. The memory chip MC and the circuit chip CC are bonded with an interface S therebetween. That is, the lower surface of the memory chip MC and the upper surface of the circuit chip CC are bonded to each other.

A region of the memory chip MC can be divided into, for example, a memory region MR, a lead region HR (not illustrated), and a pad region PR (not illustrated). The memory region MR is a region where the plurality of memory cell transistors MT (see FIG. 2) storing data are arrayed 3-dimensionally. The memory region MR occupies most of the memory chip MC and is used to store data.

As illustrated in FIG. 3, the semiconductor memory device 1 includes a stacked body 20, a plurality of slits SLT, a plurality of columnar bodies CL, and a plurality of bit lines BL (see FIG. 4) in the memory region MR. Each of the plurality of columnar bodies CL in the memory region MR corresponds to the above-described NAND string NS (see FIG. 2).

The memory region MR is partitioned into a plurality of blocks BLK by the slits SLT. That is, a region partitioned by the slits SLT corresponds to one block BLK. The columnar body CL is dotted in a plan view in the Z direction in the memory region MR. The plurality of columnar bodies CL are arrayed, for example, in zigzags (in staggered shape) in the Y direction in a plan view in the Z direction. The columnar body CL is, for example, circular or oval in a plan view in the Z direction.

A planar layout in the memory region MR of the semiconductor memory device 1 is not limited to the layout illustrated in FIG. 3 and may be another layout. For example, the number and arrangement of columnar bodies CL between the adjacent slits SLT may be changed appropriately.

As illustrated in FIG. 4, the memory chip MC of the semiconductor memory device 1 has a structure corresponding to the memory cell array 10. That is, the semiconductor memory device 1 includes the stacked body 20, the columnar body CL, and a second conductive layer 30 in the memory region MR of the memory chip MC. A first pad 36 and contacts V1 and V2 for electrical connection to the circuit chip CC are provided below the stacked body 20 so that the circuit chip CC to be described below is bonded by the first pad 36.

The second conductive layer 30 is provided above the stacked body 20 and is connected to the plurality of columnar bodies CL. The second conductive layer 30 is formed in an expanded plate shape, for example, in the X and Y directions to function as the source line SL. A metal material or the like is used as a material of the second conductive layer 30. For example, one type or two or more types of materials selected from a group consisting of titanium, titanium nitride, nickel, nickel silicide (NiSi), and P-doped silicon Si may be used. Silicide may be used as a material of the second conductive layer 30. In this case, nickel silicide, titanium silicide, or the like is used for the second conductive layer 30. A conductive layer (not illustrated) may be provided above the second conductive layer 30. For example, aluminum, titanium, titanium nitride, tungsten, or titanium nitride and aluminum may be used for the conductive layer.

The stacked body 20 includes a plurality of insulating layers 21 and a plurality of first conductive layers 31. The plurality of insulating layers 21 and the plurality of first conductive layers 31 are alternately stacked one by one in the Z direction.

The plurality of insulating layers 21 are expanded in the X and Y directions. The insulating layer 21 contains, for example, a silicon oxide. The insulating layer 21 is located between the first conductive layer 31 and the second conductive layer 30 and between the first conductive layers 31 adjacent to each other in the Z direction. The insulating layer 21 insulates two first conductive layers 31 adjacent to each other in the Z direction. The number of insulating layers 21 is determined in accordance with the number of first conductive layers 31.

The plurality of first conductive layers 31 are expanded in the X and Y directions. That is, each first conductive layer 31 is formed in an expanded plate shape in the X and Y directions. The first conductive layer 31 is, for example, a poly silicon in which tungsten or impurity is doped. The number of first conductive layers 31 is freely selected.

The first conductive layer 31 is, for example, functionally divided into three layers. The first conductive layer 31 functions as any of the source-side select gate line SGS, the word line WL, and the drain-side select gate line SGD.

Of the first conductive layers 31, at least one first conductive layer 31 from the top of the stacked body 20 functions as the source-side select gate line SGS. The first conductive layer 31 functioning as the select gate line SGS may be a single layer or a plurality of layers. That is, the select gate line SGS may be configured with one first conductive layer 31 or may be configured with the plurality of first conductive layers 31. When the select gate line SGS is configured with a plurality of layers, each first conductive layer 31 may be configured with different conductors.

Of the first conductive layers 31, at least one first conductive layer 31 from the bottom of the stacked body 20 functions as the drain-side select gate line SGD. The first conductive layer 31 functioning as the select gate line SGD may be a single layer or a plurality of layers. That is, the drain-side select gate line SGD may be configured with one first conductive layer 31 or may be configured with the plurality of first conductive layers 31. When the drain-side select gate line SGD is configured with the plurality of layers, each first conductive layer 31 may be configured with different conductors.

Of the first conductive layers 31, the first conductive layer 31 other than the select gate lines SGS and SGD functions as the word line WL. The first conductive layer 31 functioning as the word line WL surrounds, for example, the outer circumference of the columnar body CL.

The insulating layer 22 is provided below the lowermost first conductive layer 31. The conductive layer 32 is provided in the insulating layer 22. The conductive layer 32 is formed, for example, in a line shape extending in the Y direction and functions as the bit line BL. That is, in an unillustrated region, the plurality of conductive layers 32 are arrayed in the X direction.

The plurality of columnar bodies CL are provided in the stacked body 20. The plurality of columnar bodies CL extend in the Z direction. For example, the plurality of columnar bodies CL penetrate through the stacked body 20 in the Z direction. Each columnar body CL includes, for example, an insulating core 40, a semiconductor channel 41, and a memory stacked film 42.

A lower portion of the columnar body CL is in contact with the insulating layer 22. An upper portion of the columnar body CL is in contact with the second conductive layer 30. A detailed structure of the upper portion of the columnar body CL will be described below.

A columnar contact CV is provided under each columnar body CL. In the illustrated region, the contact CV corresponding to one columnar body CL is illustrated. The contact CV is connected in an unillustrated region to the columnar body CL to which the contact CV is not connected in this region. The bottom of the contact CV is in contact with one conductive layer 32 (the bit line BL).

A columnar contact V1 is provided under the conductive layer 32. A conductive layer 35 is provided under the contact V1. The conductive layers 32 and 35 are electrically connected to each other with the contact V1 interposed therebetween. The conductive layer 35 is a wiring used for connection of a circuit in the semiconductor memory device 1.

A columnar contact V2 is provided under the conductive layer 35. A first pad 36 is provided under the contact V2. The conductive layer 35 and the first pad 36 are electrically connected to each other with the contact V2 interposed therebetween. The first pad 36 is in contact with the interface S between the memory chip MC and the circuit chip CC to function as a pasting pad to the circuit chip CC. The first pad 36 contains, for example, copper.

A space 60 such as a void or a seam is provided in the insulating core 40. A configuration of the insulating core 40 will be described below.

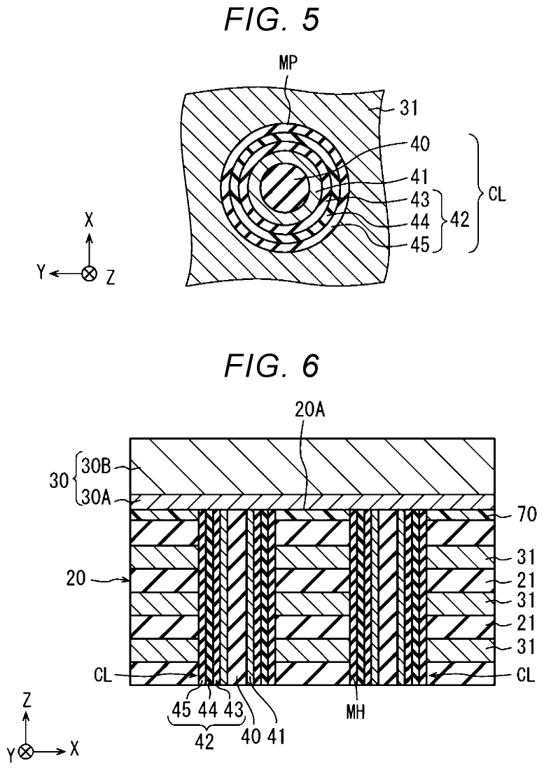

FIG. 5 is a sectional view illustrating the columnar body CL of the semiconductor memory device 1 according to the first embodiment. In the memory region MR, each of the plurality of columnar bodies CL includes the insulating core 40, the semiconductor channel 41, and the memory stacked film 42. The columnar body CL is formed in the memory hole MH and includes the insulating core 40, the semiconductor channel 41, and the memory stacked film 42 sequentially from the inner side.

The insulating core 40 has a columnar shape extending in the Z direction. The insulating core 40 contains, for example, a silicon oxide. The insulating core 40 is provided in a middle portion including a central axis of the memory hole MH when viewed in the Z direction. As illustrated in FIG. 4, the space 60 is located in the insulating core 40. In a distal end of the columnar body CL illustrated in FIG. 5, the space 60 is not located and is buried in the insulating core 40.

The semiconductor channel 41 extends in the Z direction. The semiconductor channel 41 is formed, for example, at least partially in an annular shape. An outer surface (the outer circumferential surface) of the insulating core 40 is coated with the semiconductor channel 41. The semiconductor channel 41 contains, for example, silicon. The silicon is, for example, polysilicon in which amorphous silicon is crystallized. The semiconductor channel 41 functions as a channel of each of the first select transistors S1, the plurality of memory cell transistors MT, and the second select transistor S2. The “channel” mentioned here is a flow path of carriers between a source side and a drain side.

The memory stacked film 42 extends in the Z direction. The outer surface (the outer circumferential surface) of the semiconductor channel 41 is coated with the memory stacked film 42. The memory stacked film 42 is located between the inner surface (the inner circumferential surface) of the memory hole MH and the outer surface (the outer circumferential surface) of the semiconductor channel 41. The memory stacked film 42 includes, for example, a tunnel insulating film 43, a charge storage film 44, and a block insulating film 45. These plurality of films are provided in order of the tunnel insulating film 43, the charge storage film 44, and the block insulating film 45 from the semiconductor channel 41 side.

The outer surface of the semiconductor channel 41 is coated with the tunnel insulating film 43. That is, the tunnel insulating film 43 is located between the charge storage film 44 and the semiconductor channel 41. The tunnel insulating film 43 is, for example, a silicon oxide or a silicon oxynitride film containing a silicon oxide and a silicon nitride. The tunnel insulating film 43 is a potential barrier between the semiconductor channel 41 and the charge storage film 44.

The outer surface of the tunnel insulating film 43 is coated with the charge storage film 44. That is, the charge storage film 44 is located between the insulating layer 21 and the first conductive layer 31, and the tunnel insulating film 43. The charge storage film 44 contains, for example, a silicon nitride. A portion in which the charge storage film 44 intersects each of the plurality of first conductive layers 31 functions as the transistor. The memory cell transistor MT stores data in accordance with presence or absence of charges in a portion (a charge storage portion) in which the charge storage film 44 intersects each of the plurality of first conductive layers 31 or a stored charge amount. The charge storage portion is located between each first conductive layer 31 and the semiconductor channel 41. The circumference of the charge storage portion is surrounded by an insulating material. The charge storage film 44 is an example of a “memory film”.

The block insulating film 45 inhibits back tunneling. The back tunneling is a phenomenon in which charges are returned from the first conductive layer 31 to the memory stacked film 42. The block insulating film 45 may be located between the insulating layer 21 and the first conductive layer 31 and between the first conductive layer 31 and the charge storage film 44. The block insulating film 45 is, for example, a stacked structure film in which a silicon oxide film, a metal oxide film, and a plurality of insulating films are stacked. An example of the metal oxide is an aluminum oxide.

A barrier film (not illustrated) may be provided between the block insulating film 45 and the first conductive layer 31. The barrier film improves adhesion between the first conductive layer 31 and the block insulating film 45. The barrier film is, for example, a stacked structure film of a titanium nitride or a titanium nitride and titanium.

A portion in which the columnar body CL intersects the first conductive layer 31 functioning as the select gate line SGS functions as the second select transistor S2. A portion in which the columnar body CL intersects the first conductive layer 31 functioning as the word line WL functions as the memory cell transistor MT. A portion in which the columnar body CL intersects the first conductive layer 31 functioning as the select gate line SGD functions as the first select transistor S1.

As illustrated in FIG. 4, the memory chip MC and the circuit chip CC may be pasted by the first pad 36 provided below the columnar body CL and the second pad 54 provided above a transistor Tr.

The circuit chip CC includes a substrate 50, the transistor Tr, and the second pad 54 provided above the transistor Tr. The circuit chip CC functions as a control circuit (a logic circuit) controlling an operation of the memory chip MC and has, for example, a structure corresponding to the row decoder 11, the sense amplifier 12, and the sequencer 13.

The substrate 50 is used to form the circuit chip CC. The substrate 50 is, for example, a semiconductor substrate containing P-type impurities. The transistor Tr is provided on the substrate 50. A plurality of contacts and the plurality of conductive layers are provided on the substrate 50 to correspond to a source and a drain of the transistor Tr. The plurality of conductive layers are electrically connected with contacts interposed therebetween. Of the plurality of conductive layers, the conductive layer located at the uppermost position of the circuit chip CC is the second pad 54. The second pad 54 is in contact with the interface S between the circuit chip CC and the memory chip MC to function as a pasting pad to the memory chip MC. The second pad 54 contains, for example, copper.

Each conductive layer (including the second pad 54) in the circuit chip CC is electrically connected to one bit line BL. Although not illustrated, a plurality of transistors that have structures similar to that of the transistor Tr are provided in the circuit chip CC.

Cross-sectional structures of the memory chip MC and the circuit chip CC of the semiconductor memory device 1 may be other structures. The number of wiring layers provided in the circuit chip CC can be designed to be any number. A contact connected to each conductive layer inside the circuit chip CC may be omitted appropriately in accordance with the design of the circuit. A layout of the wirings for connecting the circuit in the memory chip MC to the circuit in the circuit chip CC may be changed appropriately.

Next, a structure of a connection portion of the columnar body CL and the second conductive layer 30 (the source line SL) of the semiconductor memory device 1 will be described. FIG. 6 is a sectional view illustrating a part of the semiconductor memory device 1 according to the first embodiment. An intermediate layer 70 is provided between the first conductive layer 31 and the stacked body 20. The second conductive layer 30 serving as a source layer becomes the stacked film of conductive layers 30A and 30B. The conductive layer 30A is provided as a barrier metal and is configured as, for example, a conductor such as a stacked film (Ti/TiN) of titanium and titanium nitride. The conductive layer 30B is a main configuration film of the second conductive layer 30 and is configured as, for example, a conductor such as tungsten.

As illustrated in FIG. 6, an upper portion of the columnar body CL is in contact with the second conductive layer 30 (the source layer SL). In the columnar body CL, the upper surfaces of the insulating core 40, the semiconductor channel 41, and the memory stacked film 42 are located at an upper end of the columnar body CL. That is, the upper surfaces of the insulating core 40, the semiconductor channel 41, and the memory stacked film 42 are located at the height of an upper surface 20A of the intermediate layer 70 between the stacked body 20 and the second conductive layer 30. The upper surfaces of the insulating core 40, the semiconductor channel 41, and the memory stacked film 42 are in contact with the second conductive layer 30. The upper surface of the insulating core 40 may also be a hollow portion slightly further hollow in the −Z direction than the upper surfaces of the semiconductor channel 41 and the memory stacked film 42. In this case, the second conductive layer 30 enters the memory hole MH by the amount of the hollow portion. The upper end of the columnar body CL is formed in a substantially circular shape in a plan view in the Z direction.

The lower surface (the bottom surface) of the second conductive layer 30 is in contact with the upper surface of the semiconductor channel 41. That is, an interface between the second conductive layer 30 and the semiconductor channel 41 is located at substantially the same height as that of the insulating core 40 and the upper surface 20A of the stacked body 20. A contact portion between the semiconductor channel 41 and the second conductive layer 30 forms ohmic contact. Accordingly, the semiconductor channel 41 and the second conductive layer 30 are electrically connected to each other.

In the upper portion of the columnar body CL, a part of the memory stacked film 42 may protrude above the upper surface 20A of the intermediate layer 70. That is, at least one of the tunnel insulating film 43, the charge storage film 44, and the block insulating film 45 may protrude above the upper surface 20A of the intermediate layer 70.

As illustrated in FIG. 6, the intermediate layer 70 may be located between the second conductive layer 30 and the stacked body 20. The intermediate layer 70 is provided on a substrate SUB and functions as an etching stopper film when the memory hole MH is generated. During manufacturing, the entire intermediate layer 70 may be removed or a part of the intermediate layer 70 may remain. When a part of the intermediate layer 70 remains, the intermediate layer 70 is provided between the second conductive layer 30 and the stacked body 20. When the intermediate layer 70 is removed, the upper surface 20A becomes an upper surface of the stacked body 20. The intermediate layer 70 is formed of, for example, polysilicon, a silicon carbonitride, a silicon carbide, a High-k material (a high dielectric constant material), or an aluminum oxide.

When the intermediate layer 70 is formed of polysilicon, the intermediate layer 70 may function as a part of the second conductive layer 30. When the intermediate layer 70 is formed of a silicon carbonitride, a silicon carbide, or a High-k material (a high dielectric constant material), the intermediate layer 70 may function as an insulating film between the second conductive layer 30 and the first conductive layer 31 (the select gate line SGS).

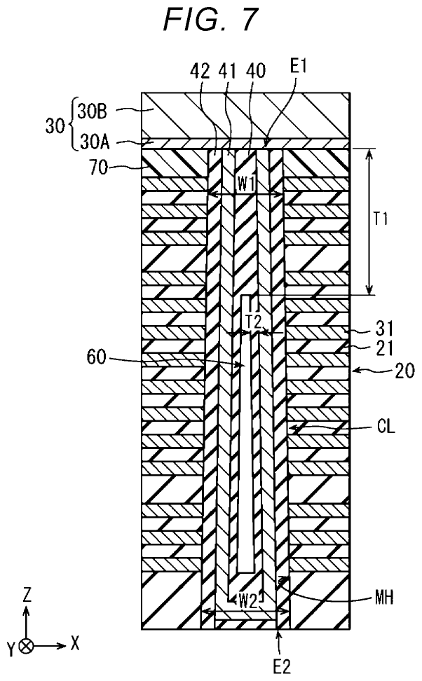

FIG. 7 is a sectional view illustrating a configuration example of the columnar body CL. The columnar body CL includes the memory stacked film 42 provided on an inner wall of the memory hole MH, the semiconductor channel 41 provided in the memory stacked film 42 in the memory hole MH, and the insulating core 40 provided in the semiconductor channel 41 in the memory hole MH. The insulating core 40 extends in the Z direction in the stacked body 20. The semiconductor channel 41 is provided between the stacked body 20 and the insulating core 40. The memory stacked film 42 is provided between the semiconductor channel 41 and the stacked body 20.

The second conductive layer 30 is provided on the stacked body 20 and is electrically connected to the semiconductor channel 41 at an end E1 of the columnar body CL. In the embodiment, the semiconductor channel 41 is located at substantially the same height as that of the insulating core 40 and the memory stacked film 42, and the second conductive layer 30 has ohmic contact with the semiconductor channel 41 at the end E1.

The space 60 such as a void or a seam is located in the insulating core 40. The insulating core 40 buries and blocks the end E1 of the columnar body CL and the inner side of the semiconductor channel 41 in the vicinity of the end E1. Accordingly, the space 60 is not provided at the end E1 and the second conductive layer 30 does not substantially enter the memory hole MH. On the other hand, the space 60 is provided near an end E2 opposite to the end E1 of the columnar body CL. That is, the space 60 is located in the insulating core 40 at a position closer to the end E2 than the end E1 of the columnar body CL. However, since the insulating core 40 blocks the inner side of the semiconductor channel 41 at the end E1 of the columnar body CL, the metal material (for example, Ti/TiN or tungsten) of the second conductive layer 30 does not enter the space 60. Accordingly, the second conductive layer 30 can inhibit deterioration in characteristics of the memory cell array.

In a step of forming the columnar body CL, the memory hole MH is formed from the end E2 to the end E1 of the columnar body CL. Accordingly, a width of the columnar body CL (a width of the memory hole MH) on a cross-sectional surface in the Z direction is decreased from the second end E2 to the first end E1, that is, as the columnar body CL is closer to the second conductive layer 30. For example, a width W1 of the first end E1 of the columnar body CL on the cross-sectional surface in the Z direction is less than a width W2 of the second end E2. In this way, the memory hole MH has a tapered portion on a side wall so that the diameter of the memory hole MH is decreased as the memory hole MH is closer to the second conductive layer 30.

A thickness T1 of the insulating core 40 at the end E1 in the Z direction is thicker than a thickness T2 of the insulating core 40 on the inner wall of the semiconductor channel 41 at a portion of the space 60.

Here, the second conductive layer 30 is formed on the surface of the stacked body 20 on the first end E1 side of the columnar body CL after the columnar body CL is formed in the stacked body 20. At this time, the memory hole MH at the end E1 is blocked by the insulating core 40, the semiconductor channel 41, and the memory stacked film 42. The thickness T1 of the insulating core 40 at the end E1 may be thicker than the thickness T2 of the insulating core 40 at a portion of the space 60. Accordingly, in a step of forming the second conductive layer 30, when the end E1 is exposed, the space 60 does not communicate with the outside at the end E1. Accordingly, the metal material (for example, Ti/TiN or tungsten) of the second conductive layer 30 does not enter the space 60 in the memory hole MH from the end E1.

In this way, according to the embodiment, the space 60 such as a void or a seam is located in the insulating core 40. The insulating core 40 blocks the end E1 of the columnar body CL and the inner side of the semiconductor channel 41 in the vicinity of the end E1. Accordingly, at the end E1 of the columnar body CL, the metal material (for example, Ti/TiN or tungsten) of the second conductive layer 30 does not enter the space 60. Accordingly, it is possible to inhibit a change in electric characteristics of the memory cell array.

### Second Embodiment

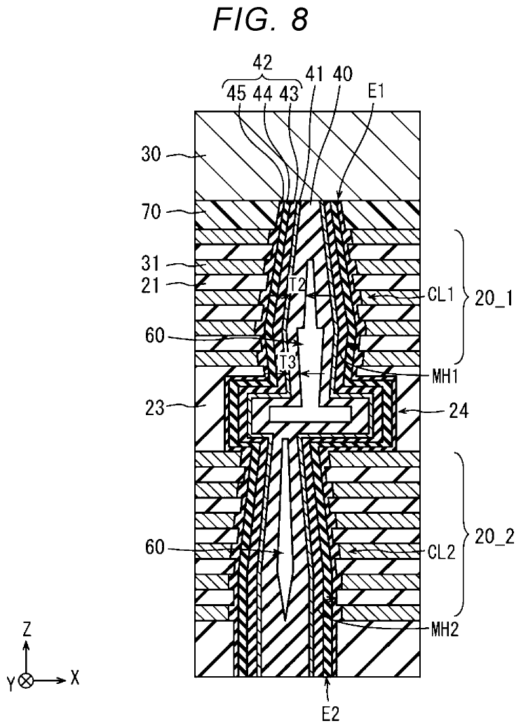

FIG. 8 is a sectional view illustrating a configuration example of the columnar body CL according to a second embodiment. In the second embodiment, the stacked body 20 includes a plurality of stacked bodies 20_1 and 20_2. The stacked body 20_1 is provided on the end E1 side and is located in the relative vicinity of the second conductive layer 30. The stacked body 20_2 is provided on the end E2 side and is spaced from the second conductive layer 30 farther than the stacked body 20_1.

A columnar body CL1 provided in the stacked body 20_1 is in contact with the second conductive layer 30. Like the columnar body CL according to the first embodiment, the columnar body CL1 includes the memory stacked film 42, the semiconductor channel 41, and the insulating core 40 formed on the inner wall of a memory hole MH1. The memory stacked film 42 includes, for example, the tunnel insulating film 43, the charge storage film 44, and the block insulating film 45.

The insulating core 40 buries and blocks the end E1 of the columnar body CL1 and the inner side of the semiconductor channel 41 in the vicinity of the end E1. Accordingly, the space 60 is not provided at the end E1 and the second conductive layer 30 does not enter the memory hole MH1. On the other hand, the space 60 is provided in a portion closer to the end E2. That is, the space 60 is provided in the insulating core 40 at a position closer to the end E2 than the end E1 of the columnar body CL1. However, since the insulating core 40 blocks the inner side of the semiconductor channel 41 at the end E1 of the columnar body CL1, the metal material (for example, Ti/TiN or tungsten) of the second conductive layer 30 does not enter the space 60. Accordingly, the second conductive layer 30 can inhibit deterioration in electrical characteristics of the memory cell array.

In a step of forming the columnar body CL1, the memory hole MH1 is formed from the end E2 side to the end E1 of the columnar body CL1. Accordingly, a width of the columnar body CL1 (a width of the memory hole MH1) on the cross-sectional surface in the Z direction is decreased from the second end E2 to the first end E1, that is, as the columnar body CL1 becomes closer to the second conductive layer 30. In this way, the memory hole MH1 has a tapered portion on a side wall so that the diameter of the memory hole MH1 is decreased as the memory hole MH1 becomes closer to the second conductive layer 30.

The thickness T1 of the insulating core 40 at the end E1 in the Z direction is thicker than thicknesses T2 and T3 of the insulating core 40 on the inner wall of the semiconductor channel 41 at a portion of the space 60. Further, in a region where there is the space 60, the thickness T2 of the insulating core 40 relatively close to the second conductive layer 30 is thicker than the thickness T3 of the insulating core 40 relatively away from the second conductive layer 30. Accordingly, the insulating core 40 easily buries (easily blocks) the end E1 of the columnar body CL and the inner side of the semiconductor channel 41 in the vicinity of the end E1.

An insulating layer 23 is provided between the stacked bodies 20_1 and 20_2. For example, a silicon oxide film is used for the insulating layer 23. A connection portion 24 that has a width in the X direction broader than the columnar bodies CL1 and CL2 is provided between the columnar bodies CL1 and CL2. The connection portion 24 connects the columnar bodies CL1 and CL2, basically has the same configuration as the configuration of the columnar bodies CL1 and CL2, and includes the memory stacked film 42, the semiconductor channel 41, and the insulating core 40.

The columnar body CL2 provided in the stacked body 20_2 is more away from the second conductive layer 30 than the columnar body CL1, is not in direct contact with the second conductive layer 30, and is in contact with the columnar body CL1.

Like the columnar body CL according to the first embodiment, the columnar body CL2 includes the memory stacked film 42, the semiconductor channel 41, and the insulating core 40 formed on the inner wall of the memory hole MH2. The memory stacked film 42, the semiconductor channel 41, and the insulating core 40 are simultaneously formed on the inner walls of the memory holes MH1 and MH2 in the same step. Accordingly, the memory stacked film 42, the semiconductor channel 41, and the insulating core 40 continue in the columnar bodies CL1 and CL2.

The insulating core 40 may bury the inner side of the semiconductor channel 41 in the columnar body CL2 or the space 60 may remain in the insulating core 40. This is because the end E1 of the columnar body CL1 is blocked by the insulating core 40, and therefore the second conductive layer 30 does not enter the memory holes MH1 and MH2 even when the space 60 remains in the insulating core 40 of the columnar body CL2.

In a step of forming the columnar body CL2, the memory hole MH2 is formed from the end E2 to the end E1 of the columnar body CL2. Accordingly, a width of the columnar body CL2 (a width of the memory hole MH2) on the cross-sectional surface in the Z direction is decreased from the second end E2 to the first end E1, that is, as the columnar body CL2 becomes closer to the columnar body CL1 or the second conductive layer 30. In this way, the memory hole MH2 has a tapered portion on a side wall so that the diameter of the memory hole MH2 is decreased as the memory hole MH2 is closer to the columnar body CL1 or the second conductive layer 30.

In this way, according to the second embodiment, the space 60 such as a void or a seam is located in the insulating core 40. The insulating core 40 blocks the end E1 of the columnar body CL1 and the inner side of the semiconductor channel 41 in the vicinity of the end E1. Accordingly, since the insulating core 40 blocks the inner side of the semiconductor channel 41 at the end E1 of the columnar body CL1, the metal material (for example, Ti/TiN or tungsten) of the second conductive layer 30 does not enter the space 60. Accordingly, in the second embodiment, it is also possible to obtain the same advantages as those of the first embodiment.

### Third Embodiment

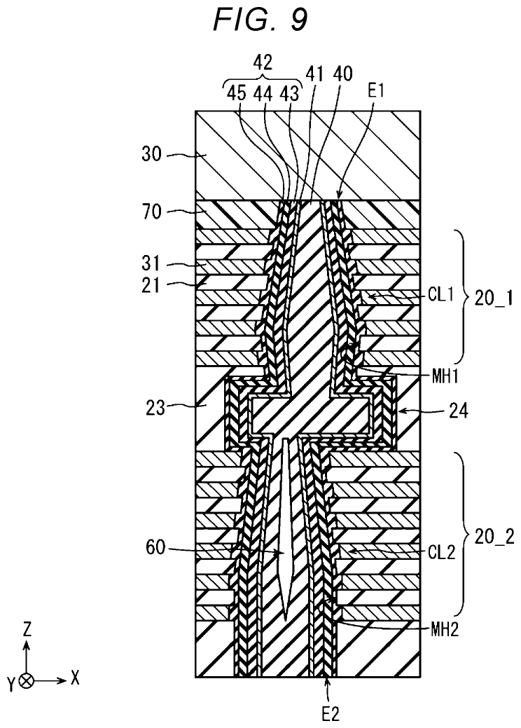

FIG. 9 is a sectional view illustrating a configuration example of the columnar body CL according to a third embodiment. In the third embodiment, the stacked body 20 includes the plurality of stacked bodies 20_1 and 20_2 as in the second embodiment. In the third embodiment, however, the space 60 is not provided in the columnar body CL1. That is, in the columnar body CL1, the inner side of the semiconductor channel 41 is filled with the insulating core 40. On the other hand, in the columnar body CL2, the space 60 is provided in the insulating core 40.

According to the third embodiment, the space 60 is in the insulating core 40 of the columnar body CL2, but is not provided in the insulating core 40 of the columnar body CL1. Accordingly, the insulating core 40 blocks the inner side of the semiconductor channel 41 of the columnar body CL1. The metal material (for example, Ti/TiN or tungsten) of the second conductive layer 30 does not enter the space 60 of the columnar body CL2. Accordingly, in the third embodiment, it is possible to obtain the same advantages as those of the first embodiment.

### Fourth Embodiment

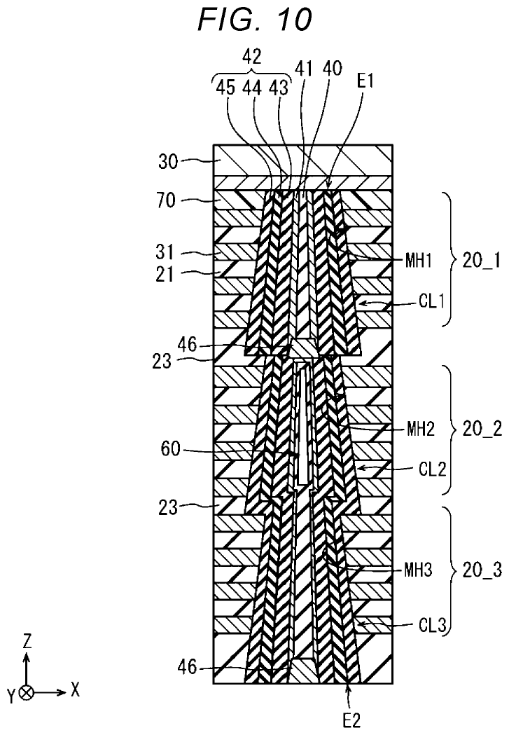

FIG. 10 is a sectional view illustrating a configuration example of the columnar body CL according to a fourth embodiment. In the fourth embodiment, the stacked body 20 includes a plurality of stacked bodies 20_1, 20_2, and 20_3. The stacked body 20_1 is located closest to the end E1 and the second conductive layer 30 among the stacked bodies 20_1, 20_2, and 20_3. The stacked body 20_2 is spaced from the second conductive layer 30 farther than the stacked body 20_1 and is located between the stacked bodies 20_1 and 20_3. The stacked body 20_3 is spaced farthest from the second conductive layer 30 among the stacked bodies 20_1 to 20_3 and is located closest to the end E2.

The columnar body CL1 provided in the stacked body 20_1 is connected to the second conductive layer 30. Like the columnar body CL according to the first embodiment, the columnar body CL1 includes the memory stacked film 42 formed on the inner wall of a memory hole MH1, the semiconductor channel 41, and the insulating core 40. The memory stacked film 42 includes, for example, the tunnel insulating film 43, the charge storage film 44, and the block insulating film 45.

The insulating core 40 buries and blocks not only the end E1 of the columnar body CL1 but also the entire inner side of the semiconductor channel 41. Accordingly, the space 60 is not provided in the semiconductor channel 41 of the columnar body CL1 and the metal material (for example, Ti/TiN or tungsten) of the second conductive layer 30 does not enter the memory hole MH1. Accordingly, the second conductive layer 30 can inhibit deterioration in characteristics of the memory cell array.

In a step of forming the columnar body CL1, the memory hole MH1 is formed from the end E2 side to the end E1 of the columnar body CL1. Accordingly, a width of the columnar body CL1 (a width of the memory hole MH1) on the cross-sectional surface in the Z direction is decreased from the second end E2 to the first end E1, that is, as the columnar body CL1 is closer to the second conductive layer 30. In this way, the memory hole MH1 has a tapered portion on a side wall so that the diameter of the memory hole MH1 is decreased as the memory hole MH1 is closer to the second conductive layer 30.

The insulating layer 23 is provided between the stacked bodies 20_1 and 20_2. For example, a silicon oxide film is used for the insulating layer 23. In FIG. 10, the connection portion 24 is not illustrated.

The columnar body CL1 has basically the same configuration as the columnar bodies CL2 and CL3 and includes the memory stacked film 42, the semiconductor channel 41, and the insulating core 40. On the other hand, in the fourth embodiment, the columnar body CL1 is formed in a step separate from steps for the columnar bodies CL2 and CL3. Accordingly, the connection portion 24 is not provided between the columnar bodies CL1 and CL2, and the memory stacked film 42, the semiconductor channel 41, and the insulating core 40 of the columnar body CL1 do not continue with those of the columnar bodies CL2 and CL3.

A conductor 46 is provided between the columnar bodies CL1 and CL2. The conductor 46 electrically connects the semiconductor channel 41 of the columnar body CL1 and the semiconductor channel 41 of the columnar body CL2. For example, a conductive material such as doped polysilicon is used for the conductor 46. The conductor 46 is provided between the insulating core 40 of the columnar body CL1 and the insulating core 40 of the columnar body CL2 and isolates the insulating core 40 of the columnar body CL1 from the insulating core 40 of the columnar body CL2.

The columnar body CL2 provided in the stacked body 20_2 is spaced from the second conductive layer 30 farther than the columnar body CL1 and is not in direct contact with the second conductive layer 30. However, the columnar body CL2 is in contact with the columnar body CL1.

Like the columnar body CL according to the first embodiment, the columnar body CL2 includes the memory stacked film 42 formed on the inner wall of the memory hole MH2, the semiconductor channel 41, and the insulating core 40. The memory stacked film 42, the semiconductor channel 41, and the insulating core 40 are formed in separate steps for the memory hole MH1 and the memory holes MH2 and MH3. Accordingly, the memory stacked film 42, the semiconductor channel 41, and the insulating core 40 are isolated between the columnar body CL1, and the columnar bodies CL2 and CL3. In the columnar body CL1 and the columnar bodies CL2 and CL3, the semiconductor channels 41 are electrically connected with the conductor 46 interposed therebetween.

The insulating core 40 may bury the inner side of the semiconductor channel 41 in the columnar body CL2. As illustrated in FIG. 10, the space 60 may remain in the insulating core 40. This is because the columnar body CL1 is blocked by the insulating core 40, and therefore the second conductive layer 30 does not enter the memory hole MH even when the space 60 remains in the insulating core 40 of the columnar body CL2.

In a step of forming the columnar body CL2, the memory hole MH2 is formed from the columnar body CL3 side to the columnar body CL1. Accordingly, a width of the columnar body CL2 (a width of the memory hole MH2) on the cross-sectional surface in the Z direction is decreased from the second end E2 to the first end E1, that is, as the columnar body CL2 is closer to the columnar body CL1 or the second conductive layer 30. In this way, the memory hole MH2 has a tapered portion on a side wall so that the diameter of the memory hole MH2 is decreased as the memory hole MH2 is closer to the columnar body CL1 or the second conductive layer 30.

The insulating layer 23 is provided between the stacked bodies 20_2 and 20_3. In FIG. 10, the connection portion 24 is not illustrated.

The columnar body CL3 provided in the stacked body 20_3 is spaced from the second conductive layer 30 farther than the columnar bodies CL1 and CL2 and is not in direct contact with the columnar body CL1. However, the columnar body CL3 is in contact with the columnar body CL2.

Like the columnar body CL according to the first embodiment, the columnar body CL3 includes the memory stacked film 42, the semiconductor channel 41, and the insulating core 40 formed on the inner wall of the memory hole MH3. The memory stacked film 42, the semiconductor channel 41, and the insulating core 40 are formed on the inner walls of the memory holes MH2 and MH3 in the same step. Accordingly, the memory stacked film 42, the semiconductor channel 41, and the insulating core 40 continue in the columnar bodies CL2 and CL3.

The insulating core 40 may bury the inner side of the semiconductor channel 41 in the columnar body CL3, as illustrated in FIG. 10. Conversely, the space 60 may remain in the insulating core 40. This is because the columnar body CL1 is blocked by the insulating core 40, and therefore the second conductive layer 30 does not enter the memory holes MH1 to MH3 even when the space 60 remains in the insulating core 40 of the columnar body CL3.

In a step of forming the columnar body CL3, the memory hole MH3 is formed from the end E2 side to the columnar body CL2. Accordingly, a width of the columnar body CL3 (a width of the memory hole MH3) on the cross-sectional surface in the Z direction is decreased from the second end E2 to the columnar body CL2, that is, as the columnar body CL3 is closer to the columnar bodies CL1 and CL2 or the second conductive layer 30. In this way, the memory hole MH3 has a tapered portion on a side wall so that the diameter of the memory hole MH3 is decreased as the memory hole MH3 is closer to the columnar bodies CL1 and CL2 or the second conductive layer 30.

At the end E2 of the columnar body CL3, the conductor 46 electrically connected to the semiconductor channel 41 is provided.

In this way, according to the fourth embodiment, the space 60 is located in the insulating core 40 of the columnar body CL2. The insulating core 40 blocks the inner side of the semiconductor channel 41 in the columnar body CL1. Accordingly, the metal material (for example, Ti/TiN or tungsten) of the second conductive layer 30 does not enter the space 60 of the columnar body CL2. Accordingly, in the fourth embodiment, it is also possible to obtain the same advantages as those of the first embodiment.

### Fifth Embodiment

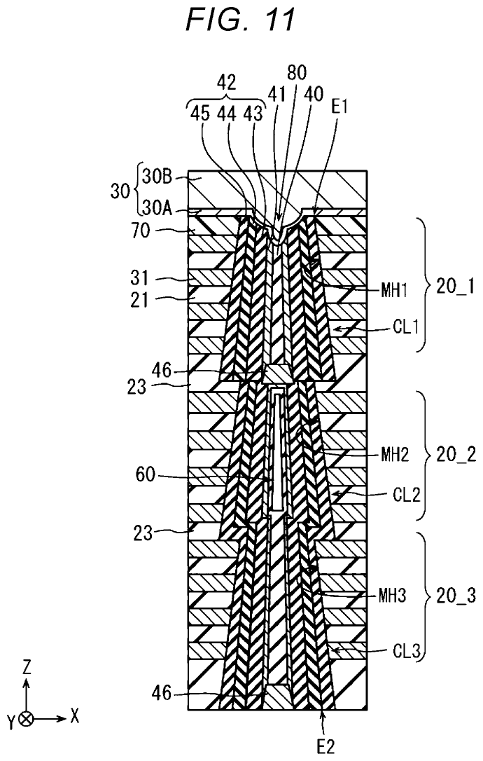

FIG. 11 is a sectional view illustrating a configuration example of the columnar body CL according to a fifth embodiment. In the fifth embodiment, the columnar body CL2 has a hollow portion 80 at the end E1. In the hollow portion 80, the insulating core 40 is hollowed toward the end E2 side further than the semiconductor channel 41 and the second conductive layer 30 is buried therein. The conductive layers 30A and 30B of the second conductive layer 30 are buried in the hollow portion 80 and are connected to the inner surface of the semiconductor channel 41. The second conductive layer 30 and the semiconductor channel 41 are connected by Schottky junction. In order for the second conductive layer 30 and the semiconductor channel 41 to be connected by ohmic contact, it is necessary to perform impurity doping with a high concentration to the semiconductor channel 41 near the second conductive layer 30. Therefore, the number of manufacturing steps increases. In the case of the Schottky junction, the impurity doping is unnecessary and the number of steps can be reduced.

A contact area of the semiconductor channel 41 and the second conductive layer 30 is larger than in the case of contact only at the end E1. Accordingly, it is possible to reduce contact resistance between the semiconductor channel 41 and the second conductive layer 30.

The fifth embodiment may be combined with any of the first to fourth embodiments. Accordingly, in the fifth embodiment, it is possible to obtain the same advantages as those of the first to fourth embodiments.

The stacked body 20 may be divided into four or more stacked bodies 20_1 to 20_n (where n is an integer of 4 or more). Even in this case, when the insulating core 40 at the end E1 with which the second conductive layer 30 is in contact sufficiently blocks the inner side of the semiconductor channel 41, it is possible to obtain the advantages of the embodiment.

Manufacturing Method 1 for Semiconductor Memory Device 1

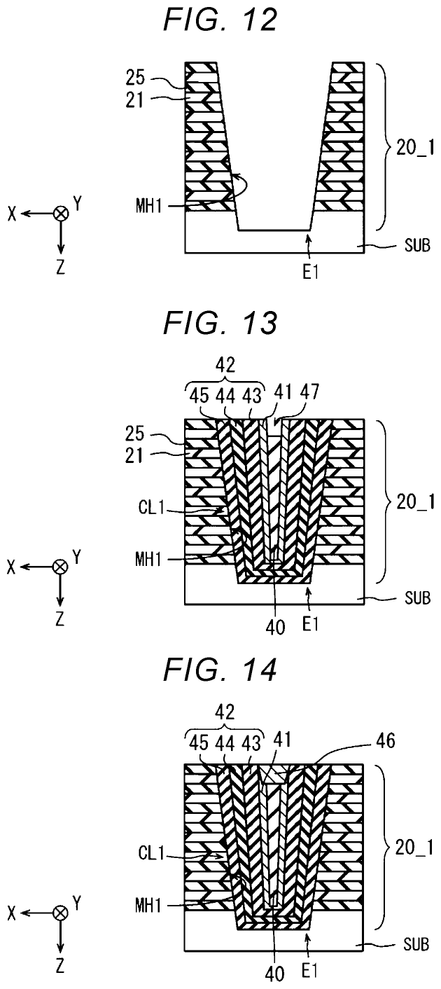

FIGS. 12 to 25 are sectional views illustrating an example of a manufacturing method according to the fourth embodiment. Since the stacked bodies 20_1 to 20_3 are formed sequentially in the order of the stacked bodies 20_1, 20_2, and 20_3, the vertical direction (the Z direction) of the structure in FIGS. 10 and 11 is reversely illustrated in FIGS. 12 to 23.

First, as illustrated in FIG. 12, the insulating layer 21 and a sacrifice film 25 are alternately stacked in the Z direction on a supporting substrate SUB to form the stacked body 20_1. The supporting substrate SUB may be, for example a semiconductor substrate such as a silicon substrate. In the insulating layer 21, for example, an insulating film such as a silicon oxide film is used. In the sacrifice film 25, for example, an insulating film such as a silicon nitride film is used. Since the sacrifice film 25 is replaced with the first conductive layer 31 in a subsequent step, the sacrifice film 25 is a material which can be selectively etched with respect to the insulating layer 21. The height of the stacked body 20_1 (a stacking number of the insulating layer 21 and the sacrifice film 25) is set to about a height at which the space 60 is not formed in the insulating core 40 which is subsequently formed.

Subsequently, the memory hole MH1 is formed in the stacked body 20_1 using a lithographic technology and an etching technology. The memory hole MH1 is formed in the Z direction from the end E2 side to the end E1 illustrated in FIG. 10 to reach the supporting substrate SUB. Accordingly, the width (the diameter) of the memory hole MH1 in the X or Y direction is relatively large in an upper end on the end E2 side and decreases as the memory hole MH1 is closer to the end E1. Although not illustrated in FIGS. 12 to 23, the intermediate layer 70 may be provided as an etching stopper of the memory hole MH1 between the supporting substrate SUB and the stacked body 20_1.

Subsequently, the block insulating film 45, the charge storage film 44, the tunnel insulating film 43, and the semiconductor channel 41 are formed on the inner wall of the memory hole MH1. Further, the insulating core 40 is buried in the semiconductor channel 41 in the memory hole MH1. For example, an insulating material such as a silicon oxide film or an aluminum oxide is used for the block insulating film 45. For example, an insulating material such as a silicon nitride film is used for the charge storage film 44. For example, an insulating material such as a silicon oxide or a silicon oxynitride film is used for the tunnel insulating film 43. For example, a conductive material such as doped polysilicon is used for the semiconductor channel 41. For example, an insulating material such as a silicon oxide film is used for the insulating core 40. The insulating core 40 is buried to the bottom of the memory hole MH1 and the space 60 is not formed in the insulating core 40.

Subsequently, until the surface of the stacked body 20_1 is exposed, the block insulating film 45, the charge storage film 44, the tunnel insulating film 43, the semiconductor channel 41, and the insulating core 40 are polished using a chemical mechanical polishing (CMP) method. Subsequently, the insulating core 40 is etched back so that a hollow portion 47 is formed on the insulating core 40. Accordingly, a structure illustrated in FIG. 13 is obtained.

Subsequently, as illustrated in FIG. 14, the conductor 46 is buried in the hollow portion 47. For example, a conductive material such as doped polysilicon is used for the conductor 46. The conductor 46 is electrically connected to the semiconductor channel 41. In this way, the columnar body CL1 extending in the Z direction is formed in the stacked body 20_1.

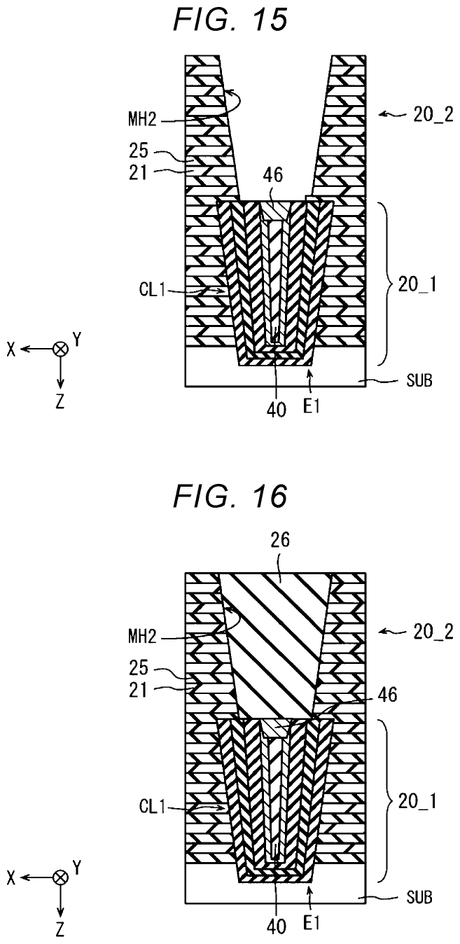

Subsequently, as illustrated in FIG. 15, the insulating layer 21 and the sacrifice film 25 are alternately stacked in the Z direction on the stacked body 20_1 to form the stacked body 20_2.

Subsequently, the memory hole MH2 is formed in the stacked body 20_2 using a lithographic technology and an etching technology. The memory hole MH2 is formed in the Z direction from the end E2 side to the end E1 side to reach the conductor 46 of the columnar body CL1. The width (the diameter) of the memory hole MH2 in the X or Y direction is relatively large in an upper end on the end E2 side and decreases as the memory hole MH2 is closer to the end E1.

Subsequently, as illustrated in FIG. 16, the sacrifice film 26 is buried in the memory hole MH2. For example, a material which can be selectively etched with respect to the insulating layer 21 and the sacrifice film 25 such as polysilicon is used for the sacrifice film 26.

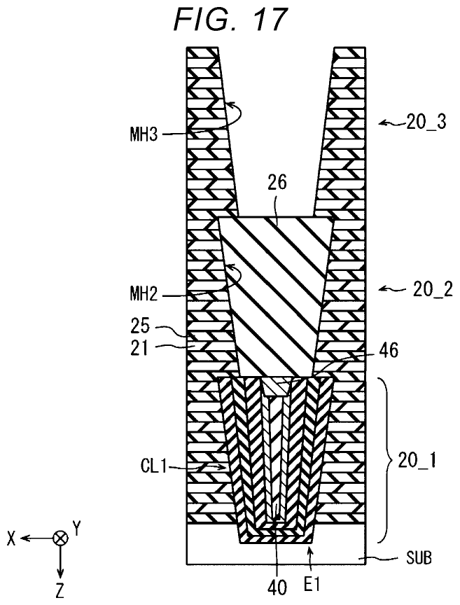

Subsequently, as illustrated in FIG. 17, the insulating layer 21 and the sacrifice film 25 are alternately stacked in the Z direction on the stacked body 20_2 to form the stacked body 20_3.

Subsequently, the memory hole MH3 is formed in the stacked body 20_3 using a lithographic technology and an etching technology. The memory hole MH3 is formed in the Z direction from the end E2 side to the end E1 side to reach the stacked body 20_2. Accordingly, the width (the diameter) of the memory hole MH3 in the X or Y direction is relatively large in an upper end on the end E2 side and decreases as the memory hole MH3 is closer to the end E1.

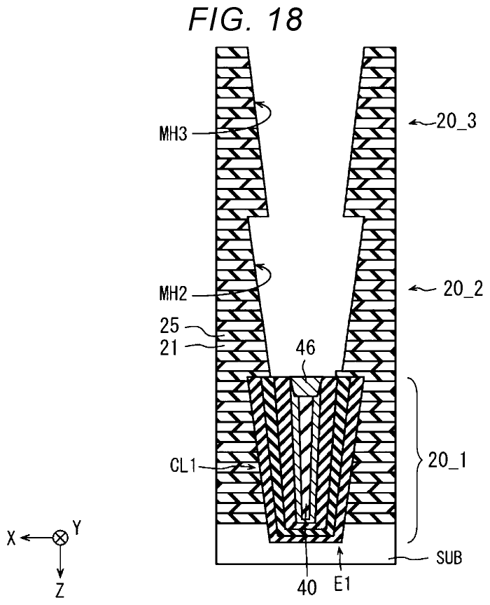

Subsequently, as illustrated in FIG. 18, the sacrifice film 26 in the memory hole MH2 is selectively removed via the memory hole MH3. Accordingly, the memory holes MH2 and MH3 communicate with each other and communicate with the conductor 46 of the columnar body CL1.

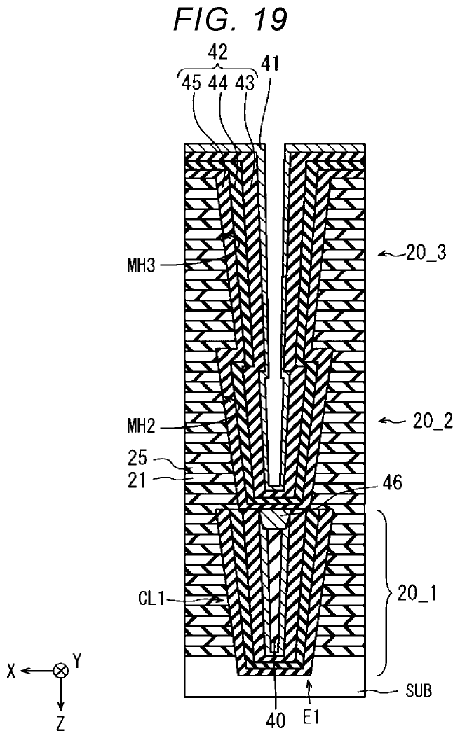

Subsequently, as illustrated in FIG. 19, the block insulating film 45, the charge storage film 44, the tunnel insulating film 43, and the semiconductor channel 41 are formed on the inner walls of the memory holes MH2 and MH3.

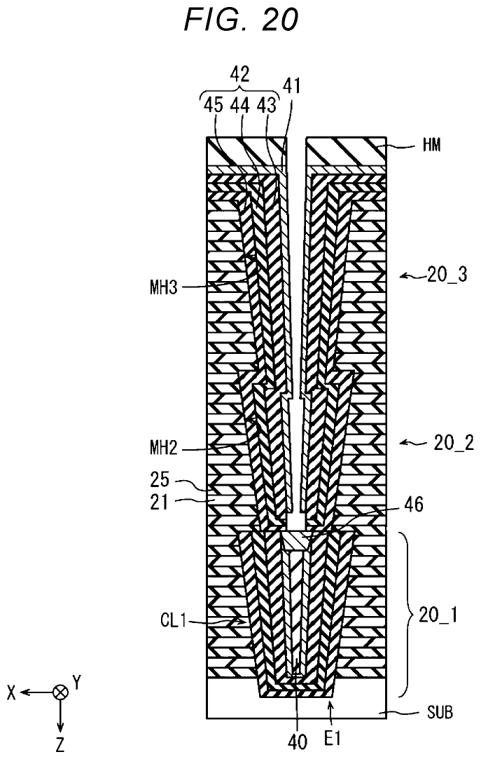

Subsequently, as illustrated in FIG. 20, a hard mask HM is formed on the stacked body 20_3. For example, an insulating material such as a silicon oxide film is used for the hard mask HM. An opening communicating with the memory hole MH3 is formed in the hard mask HM using a lithographic technology and an etching technology.

Subsequently, the semiconductor channel 41, the tunnel insulating film 43, the charge storage film 44, and the block insulating film 45 on the bottom portion of the memory hole MH2 are selectively etched using the hard mask HM as a mask. Accordingly, as illustrated in FIG. 20, the memory hole MH2 penetrates through the conductor 46 of the columnar body CL1.

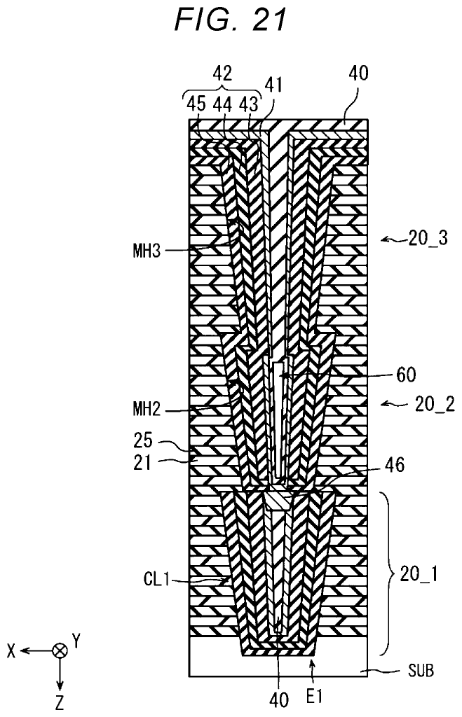

Subsequently, as illustrated in FIG. 21, the material of the semiconductor channel 41 is deposited thinly on the inner walls of the memory holes MH2 and MH3 to form the semiconductor channel 41 between the conductor 46 of the columnar body CL1 and the semiconductor channel 41 in the memory hole MH2 on the bottom portion of the memory hole MH2. Accordingly, the conductor 46 of the columnar body CL1 is electrically connected to the semiconductor channel 41 in the memory holes MH2 and MH3.

Subsequently, the material of the insulating core 40 is buried in the semiconductor channel 41 of the memory holes MH2 and MH3. At this time, the memory holes MH2 and MH3 communicate with each other and have an aspect ratio higher than that of the memory hole MH1. Accordingly, as illustrated in FIG. 21, the memory hole MH3 is blocked by the insulating core 40 with the space 60 remaining in the insulating core 40 in the memory hole MH2. The space 60 remains in the memory hole MH2 at a deep position and the space 60 does not remain in the memory hole MH3 at a shallow position.

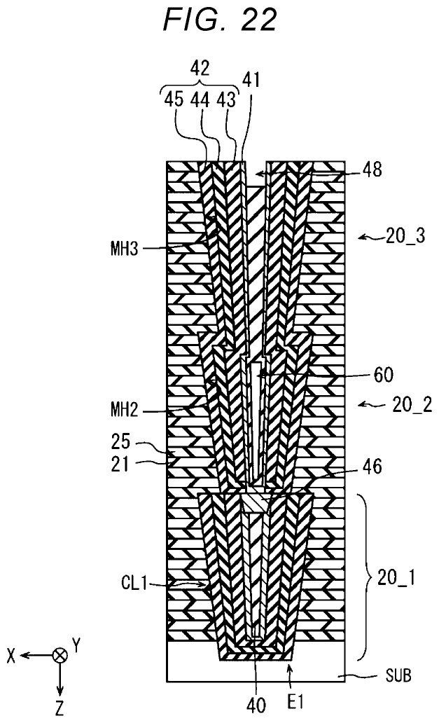

Subsequently, until the surface of the stacked body 20_3 is exposed, the block insulating film 45, the charge storage film 44, the tunnel insulating film 43, the semiconductor channel 41, and the insulating core 40 are polished using a CMP method. Subsequently, the insulating core 40 is etched back to form a hollow portion 48 on the insulating core 40. Accordingly, a structure illustrated in FIG. 22 is obtained.

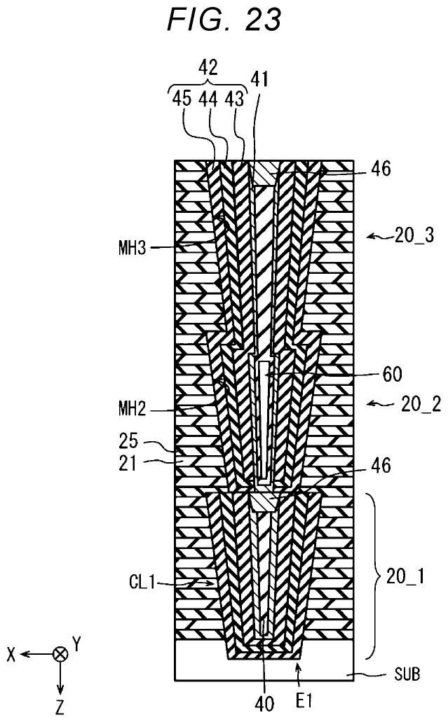

Subsequently, as illustrated in FIG. 23, the conductor 46 is buried in the hollow portion 48. The conductor 46 is electrically connected to the semiconductor channel 41. In this way, the columnar bodies CL2 and CL3 extending in the Z direction are formed in the stacked bodies 20_2 and 20_3, respectively.

Subsequently, the slits SLT in FIG. 3 remove the sacrifice film 25 via the slits SLT. Further, the material (for example, tungsten) of the first conductive layer 31 is buried in a space formed after the sacrifice film 25 is removed. Accordingly, the sacrifice film 25 of the stacked bodies 20_1 to 20_3 is replaced with the first conductive layer 31.

Subsequently, a multilayer wiring layer or the like (not illustrated) is formed on the columnar body CL3.

Subsequently, a positional relation of a structure illustrated in FIG. 23 is reversed vertically to be pasted to the circuit chip CC illustrated in FIG. 4.

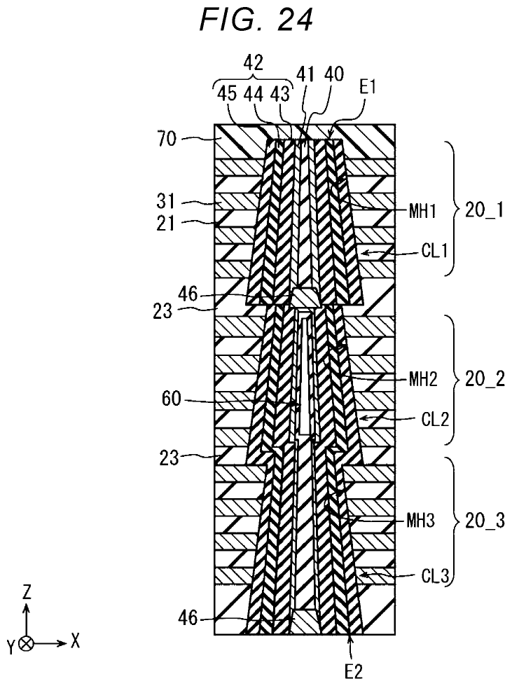

Subsequently, the supporting substrate SUB is removed. Accordingly, as illustrated in FIG. 24, the intermediate layer 70 is exposed.

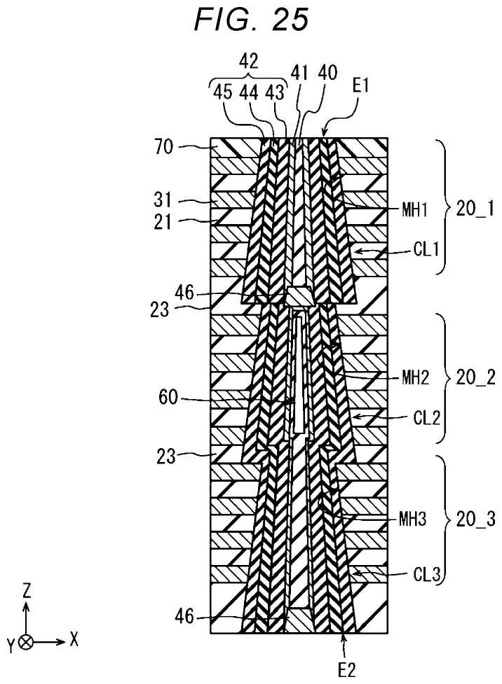

Subsequently, as illustrated in FIG. 25, the intermediate layer 70 or the like is polished until the semiconductor channel 41 is exposed further using the CMP method.

Thereafter, the conductive layer 30A is formed on the intermediate layer 70 and the columnar body CL1 and the conductive layer 30B is formed on the conductive layer 30A. The conductive layer 30A functions as a barrier metal and is configured as a stacked film of Ti and TiN. The conductive layer 30B functions as a source layer (the second conductive layer 30) along with the conductive layer 30A and is formed of, for example, a low-resistant metal material such as tungsten. Accordingly, the semiconductor memory device 1 illustrated in FIG. 10 is completed.

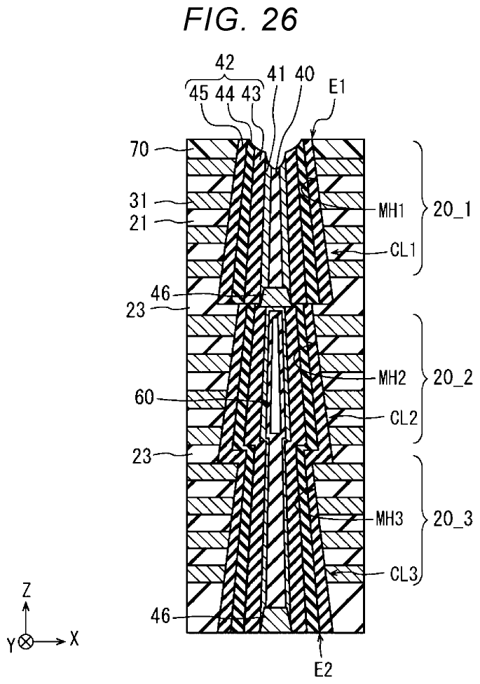

After the step illustrated in FIG. 25, as illustrated in FIG. 26, the upper portion of the insulating core 40 is etched from the end E1 to expose a part of the upper end and inner surface of the semiconductor channel 41. Thereafter, the conductive layer 30A is formed on the intermediate layer 70 and the columnar body CL1 and the conductive layer 30B is formed on the conductive layer 30A. Accordingly, the semiconductor memory device 1 illustrated in FIG. 11 is completed.

According to the embodiment, the memory hole MH1 and the columnar body CL1 of the stacked body 20_1 are formed in separate steps before the memory holes MH2 and MH3 and the columnar bodies CL2 and CL3 of the stacked bodies 20_2 and 20_3. Accordingly, the inner side of the semiconductor channel 41 in the memory hole MH1 is filled with the insulating core 40 and the space 60 is not provided in the semiconductor channel 41. Accordingly, as illustrated in FIGS. 25 and 26, although the semiconductor channel 41 is exposed at the end E1 of the columnar body CL1, the inner side of the semiconductor channel 41 is filled with the insulating core 40 without the space 60. Therefore, it is possible to inhibit the material of the conductive layers 30A and 30B from entering the space 60 unintentionally. Accordingly, it is possible to inhibit deterioration in characteristics of the memory cell array of the semiconductor memory device 1.

Manufacturing Method 2 for Semiconductor Memory Device 1

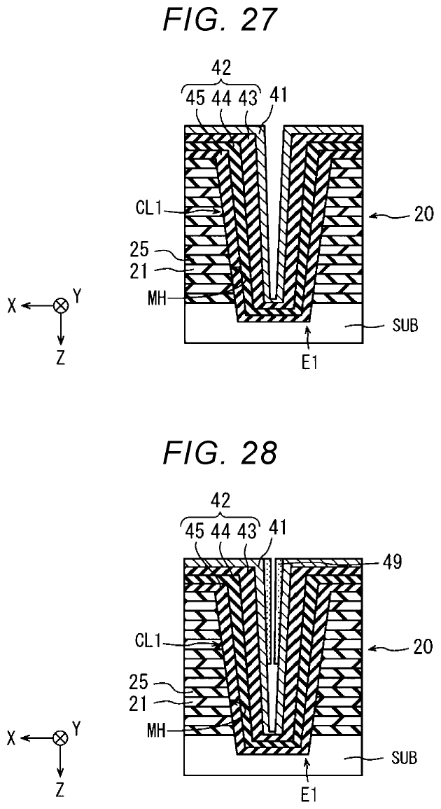

FIGS. 27 to 30 are sectional views illustrating an example of a manufacturing method according to the first embodiment. The vertical direction (the Z direction) of the structure in FIG. 7 is reversely illustrated in FIGS. 27 to 30.

After the step described with reference to FIG. 12 is performed, as illustrated in FIG. 27, the block insulating film 45, the charge storage film 44, the tunnel insulating film 43, and the semiconductor channel 41 are formed on the inner wall of the memory hole MH.

Subsequently, as illustrated in FIG. 28, plasma processing is performed on the upper inner wall of the semiconductor channel 41 in the memory hole MH to form a passivation 49 on the upper inner wall of the semiconductor channel 41. No passivation is formed on the lower inner wall of the semiconductor channel 41 by controlling a type of gas or a ratio of the gas and a flow rate of the plasma processing. In the plasma processing, it is preferable to use at least one type of gas selected from a group consisting of N₂, Ar, He, H₂, NH₃, and F.

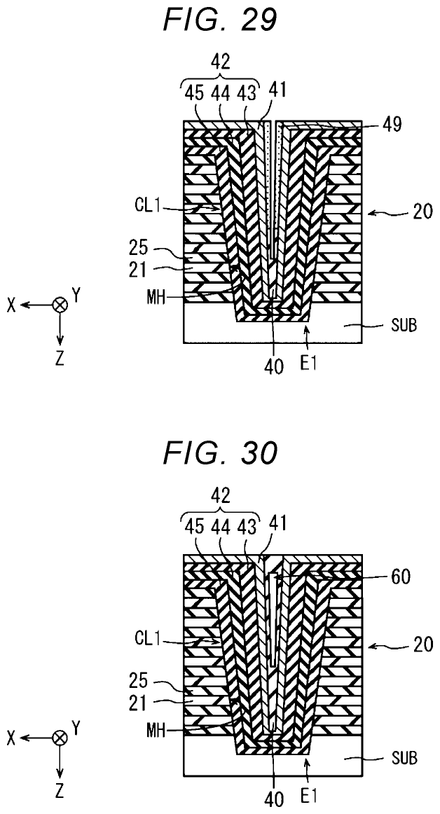

Subsequently, the insulating core 40 is deposited on the inner wall of the semiconductor channel 41 in the memory hole MH. For example, an insulating material such as a silicon oxide film is used for the insulating core 40. At this time, since the passivation 49 is formed on the upper inner wall of the semiconductor channel 41, nucleation of the material of the insulating core 40 is inhibited. Accordingly, as illustrated in FIG. 29, the insulating core 40 is not formed on the upper inner wall of the semiconductor channel 41 and is selectively formed only on the lower inner wall of the semiconductor channel 41.

After the passivation 49 is removed, the insulating core 40 is further deposited to the inner wall of the semiconductor channel 41 in the memory hole MH. Accordingly, as illustrated in FIG. 30, the material of the insulating core 40 is deposited in the entire semiconductor channel 41, and thus is formed not only on the lower inner wall of the semiconductor channel 41 but also on the upper inner wall. In the step of depositing the material of the insulating core 40 at this time, a deposition method in which a coverage is bad may be used. Accordingly, the insulating core 40 has the space 60 in on the end E2 side while the inner side of the semiconductor channel 41 is filled at the end E1 of the columnar body CL. That is, the insulating core 40 blocks the inner side of the semiconductor channel 41 on the bottom portion of the memory hole MH and has the space 60 in the insulating core 40 in the upper portion of the memory hole MH. When the inner side of the semiconductor channel 41 is filled with the insulating core 40 at the end E1 of the columnar body CL, the space 60 may remain in the insulating core 40 in the upper portion of the memory hole MH1. Thereafter, the columnar body CL is formed by the steps described with reference to FIGS. 13 and 14.

After the circuit chip CC illustrated in FIG. 4 is pasted to the end E2 side, the supporting substrate SUB is removed. Accordingly, the columnar body CL on the end E1 side is exposed. Subsequently, the intermediate layer 70 and the like are polished until the semiconductor channel 41 is exposed, as described with reference to FIGS. 24 and 25 (or FIG. 26). The conductive layer 30A is formed on the intermediate layer 70 and the columnar body CL1 and the conductive layer 30B is formed on the conductive layer 30A. Accordingly, the semiconductor memory device 1 illustrated in FIG. 4 is completed.

In the manufacturing method 2, the inner side of the semiconductor channel 41 is filled with the insulating core 40 at the end E1. Therefore, it is possible to inhibit the material of the conductive layers 30A and 30B from entering the space 60. Accordingly, it is possible to inhibit deterioration in the characteristics of the memory cell array of the semiconductor memory device 1.

Manufacturing Method 3 for Semiconductor Memory Device 1

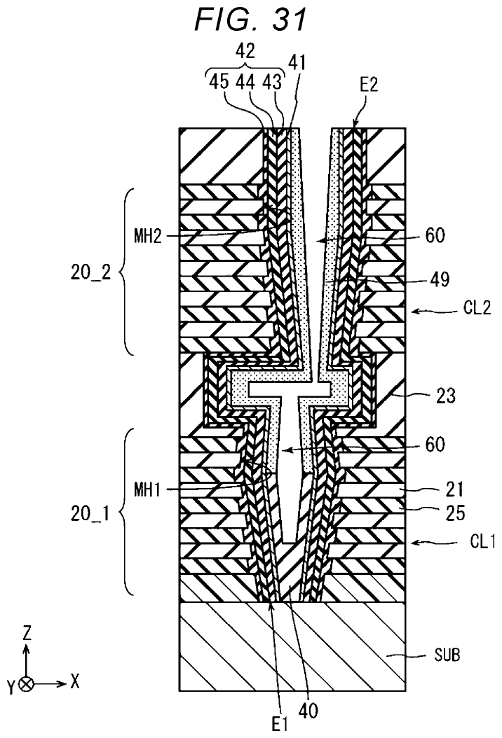

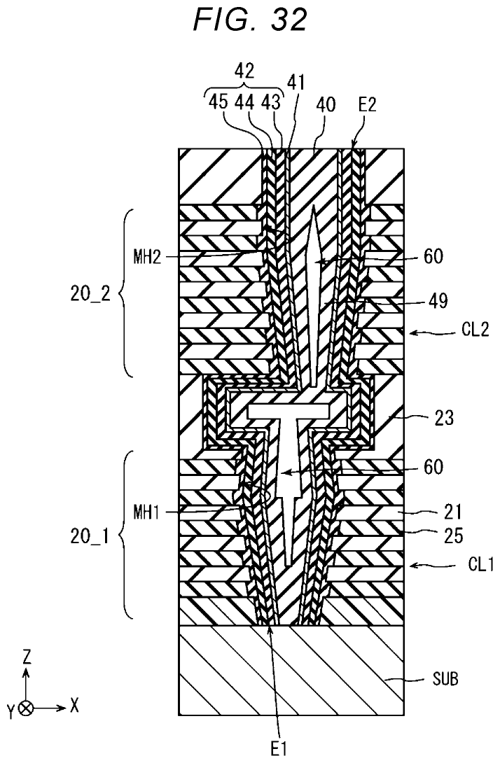

FIGS. 31 and 32 are sectional views illustrating an example of a manufacturing method according to the second embodiment. The manufacturing steps described with reference to FIGS. 27 to 30 are also performed on the columnar bodies CL1 and CL2 according to the second embodiment. For example, after the memory hole MH1 is formed in the stacked body 20_1, the insulating layer 21 and the sacrifice film are alternately stacked in the Z direction on the stacked body 20_1 to form the stacked body 20_2. Subsequently, the memory hole MH2 extending in the Z direction in the stacked body 20_2 and communicating with the memory hole MH1 is formed. Thereafter, as illustrated in FIG. 31, the block insulating film 45, the charge storage film 44, the tunnel insulating film 43, and the semiconductor channel 41 are formed on the inner walls of the memory holes MH1 and MH2.

Subsequently, as illustrated in FIG. 31, the passivation 49 is formed on the inner wall of the semiconductor channel 41 in the upper portion of the memory hole MH1 and the entire inner wall of the semiconductor channel 41 of the memory hole MH2 by performing plasma processing on the inner wall of the semiconductor channel 41 in the upper portion of the memory hole MH1 and the entire inner wall of the semiconductor channel 41 of the memory hole MH2. No passivation is formed on the inner wall of the semiconductor channel 41 in the lower portion of the memory hole MH1 by controlling a type of gas or a ratio of the gas and a flow rate of the plasma processing. In the plasma processing, it is preferable to use at least one type of gas selected from a group consisting of N₂, Ar, He, H₂, NH₃, and F.

Subsequently, the insulating core 40 is deposited on the inner wall of the semiconductor channel 41 in the memory hole MH. At this time, since the passivation 49 is formed on the upper inner wall of the semiconductor channel 41, nucleation of the material of the insulating core 40 is inhibited. Accordingly, as illustrated in FIG. 31, the insulating core 40 is not formed on the upper inner wall of the semiconductor channel 41 and is formed only on the inner wall of the semiconductor channel 41 in the lower portion of the memory hole MH1.

After the passivation 49 is removed, the insulating core 40 is further deposited to the entire inner wall of the semiconductor channel 41 in the memory holes MH1 and MH2. Accordingly, as illustrated in FIG. 32, the material of the insulating core 40 is formed on the entire lower inner wall and the entire upper inner wall of the semiconductor channel 41. Accordingly, the insulating core 40 has the space 60 in the insulating core 40 while the inner side of the semiconductor channel 41 is filled on the end E1 of the columnar body CL1. The insulating core 40 blocks the memory hole MH2 at the end E2 side. Since the insulating core 40 is formed in advance on the inner wall of the semiconductor channel 41 on the end E1 side, the insulating core 40 is formed relatively thicker (for example, T1 or T2 in FIG. 8) at the end E1 of the columnar body CL1 and is formed relatively thinner (for example, T3 in FIG. 8) at the end E2 of the columnar body CL2. Accordingly, the insulating core 40 has the space 60 in while the inner side of the semiconductor channel 41 at the end E1 is filled with the insulating core 40. When the inner side of the semiconductor channel 41 is filled with the insulating core 40 at the end E1 of the columnar body CL1, the space 60 may remain in the insulating core 40. Thereafter, the step described with reference to FIGS. 13 and 14 is performed to form the columnar bodies CL1 and CL2.

After the circuit chip CC illustrated in FIG. 4 is pasted to the end E2 side, the supporting substrate SUB is removed. Accordingly, the columnar body CL1 on the end E1 side is exposed. Subsequently, the intermediate layer 70 and the like are polished until the semiconductor channel 41 is exposed, as described with reference to FIGS. 24 and 25 (or FIG. 26). The conductive layer 30A is formed on the intermediate layer 70 and the columnar body CL1 and the conductive layer 30B is formed on the conductive layer 30A. Accordingly, the semiconductor memory device 1 illustrated in FIG. 8 is completed.

In the manufacturing method 3, the inner side of the semiconductor channel 41 is filled with the insulating core 40 at the end E1. Therefore, it is possible to inhibit the material of the conductive layers 30A and 30B from entering the space 60 unintentionally. Accordingly, it is possible to inhibit deterioration in the characteristics of the memory cell array of the semiconductor memory device 1.

In the manufacturing method according to the third embodiment, in the steps illustrated in FIG. 32, the inner side of the semiconductor channel 41 of the memory hole MH1 may be buried with the material of the insulating core 40. The other manufacturing steps according to the third embodiment may be similar to the manufacturing steps corresponding to the second embodiment.

While certain embodiments have been described, these embodiments have been presented by way of example only, and are not intended to limit the scope of the disclosure. Indeed, the novel embodiments described herein may be embodied in a variety of other forms; furthermore, various omissions, substitutions and changes in the form of the embodiments described herein may be made without departing from the spirit of the disclosure. The accompanying claims and their equivalents are intended to cover such forms or modifications as would fall within the scope and spirit of the disclosure.

What is claimed is:

1. A semiconductor memory device comprising:
a stacked body including a first insulating layer and a first conductive layer alternately stacked in a first direction;
a columnar body including:
a first insulating portion extending in the first direction in the stacked body,
a first semiconductor portion disposed between the first insulating portion and the stacked body, and
a third insulating portion disposed between a second insulating portion disposed between the first semiconductor portion and the stacked body, and the second insulating portion and the stacked body, the columnar body having a first end and a second end opposite to the first end; and
a second conductive layer disposed on the stacked body and electrically connected to the first semiconductor portion at the first end of the columnar body,
wherein the first insulating portion blocks an inner side of the first semiconductor portion at the first end of the columnar body, and the first insulating portion having a space in the first semiconductor portion at a position closer to the second end than the first end.

2. The semiconductor memory device according to claim 1,
wherein the stacked body includes a first stacked body and a second stacked body, the second stacked body further spaced from the second conductive layer than the first stacked body,
wherein the columnar body includes (i) a first columnar body extending in the first direction in the first stacked body and (ii) a second columnar body extending in the first direction in the second stacked body, and
wherein the first insulating portion in the first columnar body in the first stacked body blocks the inner side of the first semiconductor portion at the first end of the first columnar body, and the first insulating portion of the first and second columnar bodies at a position closer to the second end than the first end has a space in the first insulating portion.

3. The semiconductor memory device according to claim 1,
wherein the stacked body includes a first stacked body and a second stacked body, the second stacked body further spaced from the second conductive layer than the first stacked body,
wherein the columnar body includes a first columnar body extending in the first direction in the first stacked body and a second columnar body extending in the first direction in the second stacked body,
wherein the inner side of the first semiconductor portion is filled with the first insulating portion in the first columnar body in the first stacked body, and
wherein the first insulating portion of the second columnar body in the second stacked body has a space in the first insulating portion.

4. The semiconductor memory device according to claim 1, wherein a width of the columnar body on a cross-sectional surface of the first direction narrows as the columnar body becomes closer to the second conductive layer.

5. The semiconductor memory device according to claim 1, wherein a thickness of the first insulating portion at the first end is thicker than a thickness of the first insulating portion on an inner wall of the first semiconductor portion in a portion of the space.

6. The semiconductor memory device according to claim 1,
wherein the stacked body includes a first stacked body close to the second conductive layer, a second stacked body further spaced from the second conductive layer than the first stacked body, and a third stacked body further spaced from the second conductive layer than the second stacked body,
wherein the columnar body includes:
a first columnar body extending in the first direction in the first stacked body,
a second columnar body extending in the first direction in the second stacked body, and
a third columnar body extending in the first direction in the third stacked body,
wherein the inner side of the first semiconductor portion is filled with the first insulating portion in the first columnar body in the first stacked body,
wherein the first insulating portion of the second columnar body in the second stacked body has a space in the first insulating portion, and
wherein the inner side of the first semiconductor portion is filled with the first insulating portion in the third columnar body in the third stacked body.

7. The semiconductor memory device according to claim 1,
wherein the first insulating portion forms a hollow portion hollowed on a side closer to the second end than the first semiconductor portion at the first end, and
wherein the second conductive layer is buried in the hollow portion to be connected to an inner surface of the first semiconductor portion.

8. The semiconductor memory device according to claim 2, wherein the first insulating portion of the first stacked body is separated from the first insulating portion of the second stacked body.

9. A method of manufacturing a semiconductor memory device, the method comprising:
forming a first stacked body including alternately stacking a first insulating layer and a first sacrifice film on a material film in a first direction;
forming a first hole by extending in the first direction in the first stacked body, the first hole reaching the material film;
forming a second insulating portion, a third insulating portion, and a first semiconductor portion on an inner wall of the first hole;
forming a passivation using plasma processing on an upper inner wall of the first semiconductor portion in the first hole;
forming a first insulating portion on a lower inner wall of the first semiconductor portion having no passivation; and
depositing the first insulating portion in the entire first semiconductor portion in the first hole.

10. The semiconductor memory device according to claim 1, wherein the first conductive layer is formed of polysilicon.

11. The semiconductor memory device according to claim 1, wherein the semiconductor memory device is a nonvolatile device.

12. The semiconductor memory device according to claim 1, further comprising a memory cell array.

13. The semiconductor memory device according to claim 1, wherein the first insulating layer is formed of silicon oxide.

14. The semiconductor memory device according to claim 1, wherein the first semiconductor portion includes a semiconductor channel.

15. The semiconductor memory device according to claim 1, wherein the first semiconductor portion is formed of silicon.

16. The semiconductor memory device according to claim 1, wherein the first conductive layer is plate shaped.

17. The semiconductor memory device according to claim 1, wherein the first conductive layer is formed on tungsten.

18. The method according to claim 9, further comprising removing the sacrifice film to form a recess; and
forming a conductive layer in the recess.
